(19) United States
(12) Patent Application Publication
(10) Pub. No.: US 2008/0112517 A1
(43) Pub. Date: May 15, 2008

(54) Apparatus, methods, and computer program products providing reduced interference in a multi-antenna system

(75) Inventors: Ulo Parts, Helsinki (FI); Sami Haapoja, Helsinki (FI); Seppo Kangasmaa, Helsinki (FI)

Correspondence Address: HARRINGTON & SMITH, PC, 4 RESEARCH DRIVE, SHELTON, CT, 06484-6212, US

(73) Assignee: Nokia Corporation

(21) Appl. No.: 11/982,973

(22) Filed: Nov. 5, 2007

Related U.S. Application Data
(60) Provisional application No. 60/856,991, filed on Nov. 6, 2006.

(51) Int. Cl. H03D 1/04

(52) U.S. Cl. 375/346

(57) ABSTRACT

Exemplary embodiments of this invention substantially reduce self-interference between antennas of a multi-antenna electronic device using IRC without basing interference-minimizing effects (e.g., the covariance matrix) on attributes of the received signal. In one, non-limiting exemplary embodiment, a method includes: determining, based on at least one property, a covariance matrix for interference rejection combining (IRC), wherein the covariance matrix is determined prior to reception of a signal for which the IRC is to be used; receiving the signal; and utilizing the determined covariance matrix with the IRC to reduce self-interference of the received signal. In another exemplary embodiment, a method includes: determining at least one temporal property of self-interference for a signal prior to reception of the signal; receiving the signal; and utilizing the determined at least one temporal property to reduce self-interference of the received signal.

### CROSS-REFERENCE TO RELATED APPLICATIONS

This patent application claims priority under 35 U.S.C. §119(e) from U.S. Provisional Patent Application No. 60/856,991, filed Nov. 6, 2006, the disclosure of which is incorporated by reference herein in its entirety.

### TECHNICAL FIELD

The teachings in accordance with the exemplary embodiments of this invention relate generally to wireless communication systems and, more specifically, relate to reducing interference in a multi-antenna communication device.

### BACKGROUND

The number of different radios in mobile communication devices is steadily increasing to facilitate more flexible connectivity and a broader range of services. Cellular access alone is no longer sufficient, but new wireless technologies are being integrated in communication devices to enable novel connectivity solutions. Integration of multiple radios in a single terminal, however, introduces an integration challenge that becomes more pronounced as the number of radios increases. One element of the integration challenge is the appropriate handling of simultaneous operation of radios. It is quite evident that users are willing to use different radio connections at the same time, such as using a headset employing wireless Bluetooth® technology during a GSM (global system for mobile communication) phone call, and using a wireless local area network (WLAN) connection for Internet surfing, for example.

If there are two or more operational radio connections from one communication device, the connections may very well interfere with one another. Even if the connections are not operating on the same frequency band, they may still interfere with each other due to the non-idealities in the components of the communication device. The components may introduce spectral leakage, and the selectivity of receivers may not be ideal, meaning that they may also receive signal components belonging to a signal other than the desired one.

If there are a number of connections simultaneously operating on the same band, interference they cause to one another is more severe than if they were operating on separate bands. Especially on the 2.4 GHz unlicensed Industrial, Scientific and Medical (ISM) band, there may be several connections, for example, Bluetooth® and WLAN connections operating on the same band simultaneously. These connections cause inter-system interference with one another, which may result in a degraded quality of service. If there are two active connections on the same band operating from the same communication device, these two connections may very well interfere with each other severely, or the connections may even block each other's usage totally. This may happen because both of the connections operate from the same communication device, and thus the radio transceivers may be located within a few centimeters from each other. They may also be using the same radio components, such as an antenna, for example. If the system employs multiple antennas, the connections may utilize different antennas that operate in relatively close proximity to one another.

### SUMMARY

In an exemplary aspect of the invention, a method includes: determining, based on at least one property, a covariance matrix for interference rejection combining (IRC), wherein the covariance matrix is determined prior to reception of a signal for which the IRC is to be used; receiving the signal; and utilizing the determined covariance matrix with the IRC to reduce self-interference of the received signal.

In another exemplary aspect of the invention, a computer program product includes program instructions embodied on a tangible computer-readable medium, execution of the program instructions resulting in operations including: determining, based on at least one property, a covariance matrix for interference rejection combining (IRC), wherein the covariance matrix is determined prior to reception of a signal for which the IRC is to be used; receiving the signal; and utilizing the determined covariance matrix with the IRC to reduce self-interference of the received signal.

In a further exemplary aspect of the invention, an apparatus includes: a processor configured to determine, based on at least one property, a covariance matrix for interference rejection combining (IRC), wherein the covariance matrix is determined by the processor prior to reception of a signal for which the IRC is to be used; and a receiver configured to receive the signal, wherein the processor is further configured to utilize the determined covariance matrix with the IRC to reduce self-interference of the received signal.

In another exemplary aspect of the invention, a method includes: determining at least one temporal property of self-interference for a signal prior to reception of the signal; receiving the signal; and utilizing the determined at least one temporal property to reduce self-interference of the received signal.

In a further exemplary aspect of the invention, an apparatus includes: a processor configured to determine at least one temporal property of self-interference for a signal prior to reception of the signal; and a receiver configured to receive the signal, wherein the processor is further configured to utilize the determined at least one temporal property to reduce self-interference of the received signal.

### BRIEF DESCRIPTION OF THE DRAWINGS

The foregoing and other aspects of embodiments of this invention are made more evident in the following Detailed Description, when read in conjunction with the attached Drawing Figures, wherein:

FIG. 1 shows a simplified block diagram of various electronic devices that are suitable for use in practicing the exemplary embodiments of this invention;

FIG. 2 illustrates an exemplary architecture for the communication device depicted in FIG. 1;

FIG. 3 depicts a flowchart illustrating one non-limiting example of a method for practicing the exemplary embodiments of this invention;

FIG. 4 depicts a flowchart illustrating another non-limiting example of a method for practicing the exemplary embodiments of this invention;

FIG. 5 depicts a flowchart illustrating another non-limiting example of a method for practicing the exemplary embodiments of this invention; and

FIG. 6 depicts a flowchart illustrating another non-limiting example of a method for practicing the exemplary embodiments of this invention.

### DETAILED DESCRIPTION

Commonly-assigned U.S. Patent Publication No. 2006/0135076 (U.S. patent application Ser. No. 11/283,792) to Honkanen et al., titled “Method and Device for Controlling Radio Access,” describes a method for controlling a number of simultaneous radio connections in a communication device. The control of a number of simultaneous radio connections is carried out in the communication device. Parameters of the radio connections are controlled such that interference between the radio connections is minimized. Specifically, the method for creating a new radio connection in a communication device with at least one existing radio connection involves: determining whether or not the existing radio connection and the new radio connection interfere with one another; and creating the new radio connection with parameters that minimize interference between the existing radio connection and the new radio connection if the existing radio connection and the new radio connection interfere with one another.

As explained in the Background Section of U.S. Pat. No. 6,128,355 to Backman et al., titled “Selective Diversity Combining,” one method of combining received signals in a system with antenna diversity is known as interference rejection combining (IRC). Generally, IRC is a method to determine antenna combining weights to combine the signals received by multiple antenna branches. IRC takes the correlation of the interference and noise between diversity branches into account. IRC has numerous applications including, for example, in the context of MIMO (multiple-input multiple-output) for suppressing mutual interference from parallel data streams.

IRC assumes that the received signals include both white Gaussian noise and signals from other transmitters (e.g., other mobile stations in other cells). Generally speaking, a receiver incorporating IRC produces received signal samples for each antenna (e.g., using log-polar signal processing), estimates channel taps for each antenna, estimates impairment correlation properties (e.g., co-channel interference), forms branch metrics from the received signal samples, channel tap estimates, and impairment correlation estimates, and estimates the transmitted information sequence using the branch metrics (e.g., using the Viterbi algorithm). The receiver estimates impairment correlation properties by estimating the correlated noise between signal branches when a training sequence (such as is contained in a typical GSM burst) is received. This estimated covariance is used by the receiver during the demodulation process.

As further explained in commonly-assigned U.S. Patent Publication No. 2006/0203894 (U.S. patent application Ser. No. 11/091,576) to Ventola, titled “Method and Device for Impulse Response Measurement,” the goal of IRC is to maximize the instantaneous Signal to Interference plus Noise Ratio (SINR). IRC requires knowledge of the channel and the covariance matrix of interference plus noise. The combiner weights of the IRC can be calculated by
ŵ=ĉₙₘ⁻¹hĥ, (1)

where ĉₙₘ is an estimate of the covariance matrix of interference plus noise, (.)⁻¹ denotes matrix inversion and ĥ is a column vector that contains the channel estimates. The covariance matrix estimation and matrix inversion are known to a person of ordinary skill in the art.

IRC is further described in: U.S. Pat. No. 5,680,419 to Bottomley, titled “Method and Apparatus for Interference Rejection Combining in Multi-Antenna Digital Cellular Communications Systems;” commonly-assigned U.S. Patent Publication No. 2001/0017883 (U.S. patent application Ser. No. 09/821,931) to Tiirola et al., titled “Rake Receiver;” commonly-assigned U.S. Patent Publication No. 2004/0042532 (U.S. patent application Ser. No. 10/450,610) to Artamo et al., titled “Measuring Method, and Receiver;” commonly-assigned U.S. Patent Publication No. 2004/0114695 (U.S. patent application Ser. No. 10/472,263) to Astely et al., titled “Interference Rejection in a Receiver;” commonly-assigned U.S. Patent Publication No. 2005/0101253 (U.S. patent application Ser. No. 10/760,532) to Pajukoski et al., titled “Communication Method, Receiver and Base Station;” and Tiirola et al., “Performance of Smart Antenna Receivers in WCDMA Uplink With Spatially Coloured Interference,” IST Mobile Communications Summit, Sep. 9-12, 2001, Barcelona, Spain.

Reference with regard to an analytical description of interference covariance matrices as relating to OFDM (Orthogonal Frequency Division Multiplexing) systems may be made to Hutter et al., “Determination of Intercarrier Interference Covariance Matrices and their Application to Advanced Equalization for Mobile OFDM,” 5th International OFDM-Workshop, 2000, Hamburg, pp. 33-1 to 33-5.

The exemplary embodiments of the invention provide improved techniques for reducing self-interference. More specifically, exemplary embodiments of the invention do not utilize a measurement of the received signal for IRC. Instead, exemplary embodiments of the invention utilize different information, such as temporal properties or spatial properties, as non-limiting examples. Exemplary embodiments of this invention substantially reduce self-interference between antennas of a multi-antenna electronic device using IRC without basing interference-minimizing effects (e.g., the covariance matrix) on attributes of the received signal.

In one exemplary embodiment, the covariance matrix is determined prior to reception of the signal by utilizing at least one property, such as a spatial property (e.g., antenna geometry) or a temporal property (e.g., knowing the timing of the self-interference). The signal is received and, subsequently, the determined covariance matrix is utilized with the IRC to reduce self-interference of the received signal.

In another exemplary embodiment, at least one temporal property of self-interference for the signal is determined prior to reception of the signal. The signal is received and, subsequently, the determined at least one temporal property is utilized to reduce self-interference of the received signal.

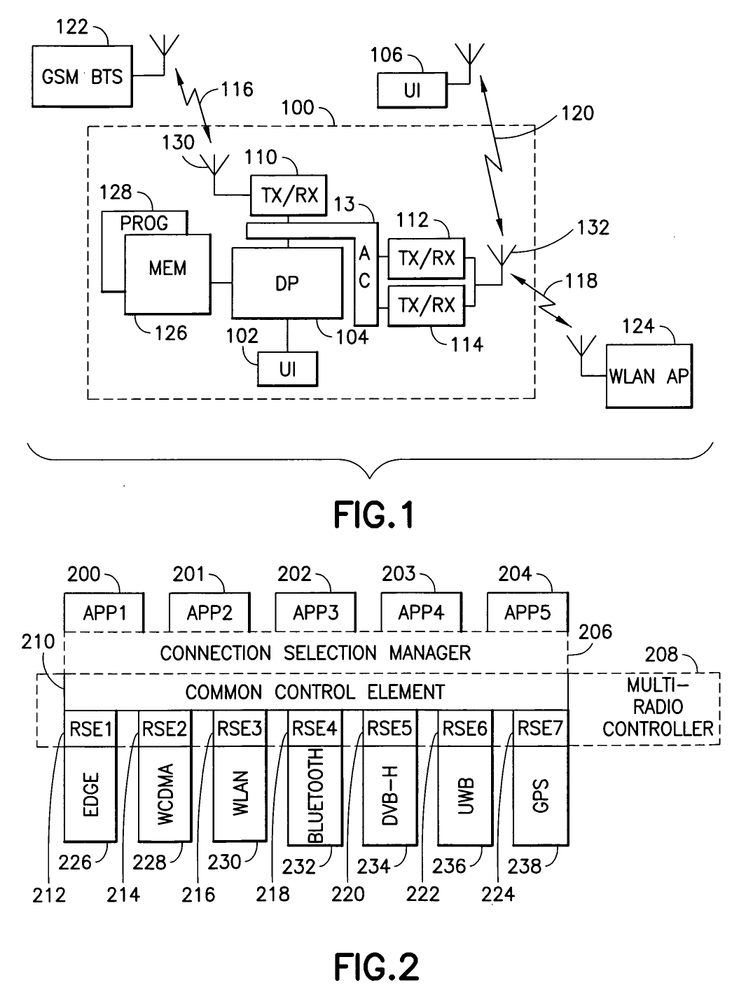

FIG. 1 shows a simplified block diagram of various electronic devices that are suitable for use in practicing the exemplary embodiments of this invention. The electronic device (communication device) 100 employs a number of simultaneous radio connections as will be described below. In general, the various embodiments of the communication device 100 can include, but are not limited to, cellular telephones, personal digital assistants (PDAs) having wireless communication capabilities, portable computers having wireless communication capabilities, image capture devices such as digital cameras having wireless communication capabilities, gaming devices having wireless communication capabilities, music storage and playback appliances having wireless communication capabilities, Internet appliances permitting wireless Internet access and browsing, as well as portable units or terminals that incorporate combinations of such functions. The communication device 100 may also comprise a combination of two electronic devices, such as a computer with a mobile communication device coupled to the computer. As a non-limiting example, the communication device 100 may comprise a mobile communication device such as the Nokia Communicator®.

The communication device 100 comprises a number of communication interfaces 110, 112, 114 with each configured to provide one or more communication connections (e.g., wireless radio connections). The communication interfaces 110, 112, 114 may be configured to provide connections employing different radio access technologies. In FIG. 1, one communication interface 110 provides a communication link 116 with a GSM (global system for mobile communications) system through a serving GSM base transceiver station (BTS) 122. Another communication interface 114 provides a WLAN connection 118 with a serving WLAN access point (AP) 124. A third communication interface 112 provides another wireless connection 120, using Bluetooth®-technology, with a user interface (UI) component 106. As a non-limiting example, the UI component 106 may be a headset of a mobile telephone, comprising a microphone, a loudspeaker, and a communication interface for a Bluetooth® connection with the communication device 100. As additional non-limiting examples, the UI component 106 may comprise a keyboard or a mouse operating with a computer through a Bluetooth® link. The UI component 106 may comprise a component or device that is internal to the communication device 100 or external to the communication device 100.

The communication interfaces 110, 112, 114 described above may utilize one or more same components of the communication device 100 during operation of the radio connections 116, 118, 120. The communication interfaces 110, 112, 114 may, for example, utilize a same antenna or antennas, a same radio frequency amplifier, and/or a same radio frequency filter. One or more of the communication interfaces 110, 112, 114 may naturally have its own components or some of the communication interfaces 110, 112, 114 may utilize the same components.

In the exemplary system shown in FIG. 1, three communication interfaces 110, 112, 114 are shown as being utilized by the communication device 100, these interfaces 110, 112, 114 providing the GSM connection 116, the Bluetooth® connection 120 and the WLAN connection 118, respectively. It should, however, be appreciated that the communication device according to the exemplary aspects of the invention is not limited to the number of communication interfaces nor to the wireless communication technologies the communication interfaces provide as shown in FIG. 1. Thus, the communication device may comprise several communication interfaces providing connections based on the following technologies, as non-limiting examples: GSM, WLAN, Bluetooth®, WCDMA (wideband code division multiple access), GPRS (general packet radio service), EDGE (enhanced data rates for GSM evolution), DVB-H (digital video broadcasting for handheld devices), UWB (ultra wideband), GPS (global positioning system), CDMA, CDMA2000, UTRA (universal terrestrial radio access) and E-UTRA/LTE (evolved universal terrestrial radio access/long term evolution of UTRA). Other wireless communication technologies may also be utilized in conjunction with the exemplary embodiments of the invention.

The communication device 100 includes a data processor (DP) 104 and a memory (MEM) 126 coupled to the DP 104. The MEM 126 stores a program (PROG) 128. Note that the DP 104 is coupled to the communication interfaces 110, 112, 114 via an antenna combiner (AC) 134, as further described below. Further note that each communication interface 110, 112, 114 comprises a suitable RF transceiver (having a transmitter (TX) and a receiver (RX)) for wireless communication (e.g., bidirectional). Each communication interface 110, 112, 114 is coupled to an antenna 130, 132, though, as noted above, each communication interface 110, 112, 114 may or may not use a separate antenna (i.e., more than one communication interface may use the same antenna, such as with antenna 132 of FIG. 1).

The DP 104, in conjunction with the MEM 126 and PROG 128, is configured to control at least some functions of the device 100, such as creating radio connections between the communication device 100 and other communication devices or networks, such as a GSM network (e.g., via a GSM BTS 122) or a WLAN (e.g., via a WLAN AP 124), for example. The DP 104 further may be configured to control a number of simultaneous radio connections in the communication device 100. The MEM 126 may be of any type suitable to the local technical environment and may be implemented using any suitable data storage technology, such as semiconductor-based memory devices, magnetic memory devices and systems, optical memory devices and systems, fixed memory and removable memory, as non-limiting examples. The DP 104 may be of any type suitable to the local technical environment, and may include one or more of general purpose computers, special purpose computers, microprocessors, digital signal processors (DSPs) and processors based on a multi-core processor architecture, as non-limiting examples. As further non-limiting examples, the DP 104 may be implemented with a digital signal processor with suitable software or with separate logic circuits, for example with one more ASICs (Application Specific Integrated Circuits). The DP 104 may also comprise a combination of two or more of these implementations, such as a processor with suitable software embedded within an ASIC, for example.

The communication device 100 further may comprise a user interface (UD 102 coupled to the DP 104. The UI 102 may comprise one or more keyboards, touchpads, microphones, speakers, displays, and/or cameras, as non-limiting examples.

The communication device 100 may comprise an antenna combiner 134 coupled to the data processor and the plurality of antennas 130, 132. The antenna combiner 134 may be located between the DP 104 and the communication interfaces 110, 112, 114 or between the communication interfaces 110, 112, 114 and the antennas 130, 132, as non-limiting examples. The antenna combiner 134 is coupled to the plurality of antennas and thus enables a single component to control or otherwise affect all of the signals passing through the antennas (i.e., both transmitted and received signals). In other exemplary embodiments, the antenna combiner 134 may not be present in the communication device 100. If an antenna combiner 134 is present, the antenna combiner 134 may perform the functions otherwise associated with the communication interfaces 110, 112, 114 of FIG. 1. In such a manner, the antenna combiner 134 may be configured to process transmitted and/or received radio signals.

The communication device 100 usually comprises a voltage source (not shown) to provide current for the operation of the device 100. The voltage source may comprise a rechargeable battery or one or more fuel cells, as non-limiting examples.

The exemplary embodiments of the invention, as further described below, may be implemented in one or more of: the DP 104, the PROG 128, the AC 134 and/or one or more of the communication interfaces 110, 112, 114, as non-limiting examples.

FIG. 2 illustrates an exemplary architecture for the communication device 100 depicted in FIG. 1. The architecture is depicted in a layered form, as in an OSI (Open Systems Interconnection) model of ISO (International Organization for Standardization), with lower layers providing services to higher layers.

On the highest layer are provided applications (APP1 to APP5) 200-204 that may need a radio connection. The application 200-204 may be an application handling a voice call, a web or WAP (Wireless Application Protocol) browser, an e-mail client, a GPS navigation application, a gaming application, or a media player application, as non-limiting examples. Whenever an application 200-204 intends to utilize a radio connection to another communication device or network, the application sends a request to a lower layer to establish the connection. During the operation of the connection, the application sends data related to the application to lower layers for transmission over the connection to the other communication device or system. Similarly, the application receives data related to the application from the other communication device or system via the connection through the lower layers. When a need no longer exists to maintain the connection, the application sends a request to a lower layer to terminate the connection.

On the lower layer, services may be provided to the applications 200-204 by a connection selection manager 206. The connection selection manager 206 may select an appropriate connection for an application based on a set of connection profiles stored in a database, for example. A user or an operator, for example, may define the connection profiles, and the profiles may be based on optimization of some criterion such as throughput, bit error rate or cost-efficiency of the connection, as non-limiting examples. The connection selection manager 206 is an optional layer in the architecture of the communication device 100, since there are other methods by which the connections can be selected and/or manages. As a non-limiting example, the applications 200-204 may be designed to define the suitable connections by themselves.

The next lower layer is a multiradio controller 208. The multiradio controller 208 establishes, controls, and terminates radio connections according to the connection requirements from the higher layers. The multiradio controller 208 is also responsible for taking care of the simultaneous operation of multiple radio connections.

As a non-limiting example, the multiradio controller 208 may be a two-fold entity. First, there is a common control element 210 which communicates with the higher layers. The common control element 210 receives requests for creating and terminating radio connections from the applications 200-204 or, if utilized, the connection selection manager 206. The common control element 210 may also check the availability of the radio connection requested from a higher layer, and either start a process for creating a radio connection or inform higher layers that the requested radio connection is not currently available. The common control element 210 may also be responsible for controlling the simultaneous operation of multiple radio connections.

The multiradio controller 208 also comprises radio-specific entities 212-224. Each radio-specific entity may be seen as an interface between the common control element 210 of the multiradio controller 208 and the respective specific radio interface. A radio-specific entity controls one corresponding radio connection according to the parameters received from the common control element 210. A radio-specific entity is close to the physical layer of the connection, which enables rapid adaptation to a changing environment and fast control of the connection. The functionality of each radio-specific entity is radio-system-specific, which means that the parameters from the common control element 210 are applied to the standard specifications of the respective radio system. A radio-specific entity may also supply the common control element 210 with one or more measured properties of the connection it controls. The measured properties of the connection may comprise the bit error rate (BER), block error rate, or the frame error rate (FER) of the connection, as non-limiting examples. The measured properties may also comprise received energy per chip divided by the noise power density in the band (Ec/No), interference signal code power (ISCP), received signal code power (RSCP), received signal strength indicator (RSSI), and signal-to-interference-power ratio (SIR), as further non-limiting examples.

In another exemplary embodiment of the multiradio controller, radio-specific entities are not included in the multiradio controller. Instead, the multiradio controller may have an interface to an external entity providing the interface to each radio.

As shown in FIG. 2, below the radio-specific entities 212-224 the communication interfaces 226-238 are provided. Each communication interface 226-238 is responsible for encoding and decoding data into suitable electrical waveforms for transmission and reception on the specific physical media used. This process is carried out according to each radio-access-specific standard. The architecture of FIG. 2 employs physical layers of EDGE, WCDMA, WLAN, Bluetooth®, DVB-H, UWB and GPS radio access technologies, but the operation of the multiradio controller is not limited to these technologies as it can be configured to control other wireless radio access technologies or other combinations of wireless radio access technologies.

Although an exemplary architecture is described as shown in FIG. 2, other suitable architectures may be employed in conjunction with the exemplary embodiments of the invention as further described herein.

As explained above, utilizing IRC, antenna combining weights are calculated by using a covariance matrix such that the SINR ratio is maximized in the combined signal. In conventional IRC, the covariance matrix is measured from the received signal. However, employing aspects of the exemplary embodiments of this invention, self-interference information may be used in one of at least two ways: (1) by knowing the instance of time when the self-interference occurs; or (2) obtaining antenna combining weights (i.e., using a covariance matrix) based on pre-tabulation (i.e., without using attributes of the received signal). Note that for the first aspect, at those particular time instances the covariance matrix estimated from the received signal is not used.

Using the second aspect, the covariance matrix is tabulated prior to receiving the signal and, thus, the covariance matrix is not based on the received signal. The calculation is accomplished using various known and/or measured attributes of the electronic device and/or signals other than the received signal (e.g., an interfering transmitted signal).

The following are provided as non-limiting examples of the attributes that may be considered in determining the covariance matrix for IRC in accordance with the exemplary embodiments of the invention. The non-limiting examples provided may be utilized alone or together, in suitable combinations. Utilizing the architecture of or one similar to that of FIG. 2, the multiradio controller may provide the time instance. The self-interference properties may be predefined for the correct instance of time and bandwidth area of the receiver. Spatial properties may be calculated beforehand by knowing the antenna geometry and/or correlation properties of the interference-causing transmit antenna. Spatial properties may also be calculated using the antenna geometry and/or correlation properties of the receive antenna.

The information and attributes required for the utilized model and accompanying covariance matrix may be: known, predefined or set by the electronic device; obtained by measurements made at or substantially temporally close to the desired application of the covariance matrix (e.g., measurements made of signals or features other than the received signal); and/or obtained by measurements made prior to receiving the received signal. If based on measurements, the measurements may be performed by the electronic device and/or by other equipment. Furthermore, any such measurements may be performed prior to, at or subsequent to sale or transfer (temporary or permanent) of the electronic device to a user.

The exemplary embodiments of the invention may be implemented in any suitable component or components of the electronic device, including, as non-limiting examples: one or more data processors, an antenna combiner or an IRC combiner.

As a non-limiting example, to adequately estimate interference covariance, averaging over time and/or frequency bandwidth (e.g., over subcarriers in an OFDMA system) may be utilized and/or needed.

In some cases, self-interference may appear for only a fraction of the bandwidth and/or for a short instance of time. In such cases, there may be a large error in interference covariance matrix estimation without utilizing self-interference knowledge (e.g., without the assistance of a multiradio controller).

The multiradio controller may be used to obtain the signature (e.g., time, frequency, spatial properties) of the transmitted interfering signal. The signature may then be utilized by the communication equipment when receiving a signal to suppress the effects of the interference. In such a manner, simultaneous reception of a desired signal may be enabled.

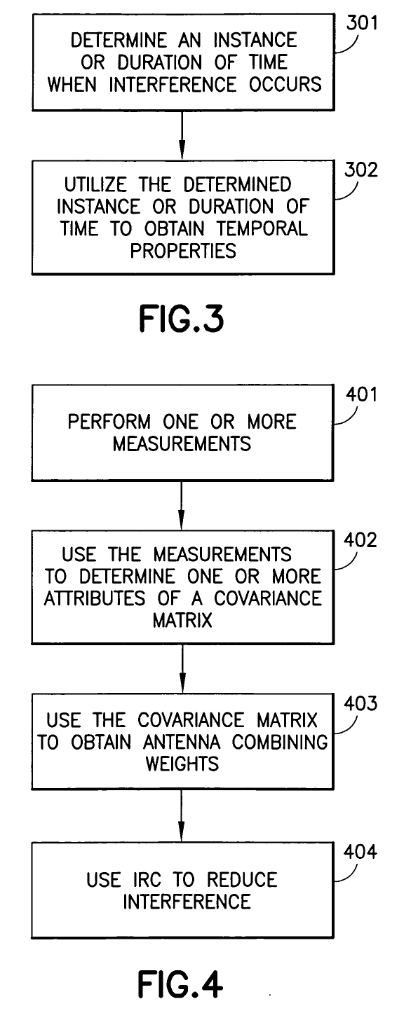

FIG. 3 depicts a flowchart illustrating one non-limiting example of a method for practicing the exemplary embodiments of this invention. In box 301, an instance or duration of time when interference occurs is determined. In box 302, the instance or duration of time is utilized to obtain the temporal properties of an interference covariance matrix.

FIG. 4 depicts a flowchart illustrating another non-limiting example of a method for practicing the exemplary embodiments of this invention. In box 401, one or more measurements are performed. In box 402, the measurements are used to determine one or more attributes of an interference covariance matrix. In box 403, the interference covariance matrix is used to obtain a plurality of antenna combining weights. In box 404, interference rejection combining (IRC), based on the antenna combining weights, is utilized to reduce interference.

The methods shown in FIGS. 3 and 4 may be utilized separately or together. Furthermore, the exemplary methods depicted may be modified or adapted based on the preceding discussion and descriptions. As a non-limiting example of such an adaptation, the exemplary methods shown may be implemented in any suitable component or components of the electronic device, including, as non-limiting examples: one or more data processors, an antenna combiner or an IRC combiner

Based on the foregoing, it should be appreciated that at least one advantage that can be realized by the use of the exemplary embodiments of this invention is that self-interference between a transmit antenna and a receive antenna of a multi-antenna electronic device using IRC may be substantially reduced without basing interference-minimizing effects (e.g., the covariance matrix) on attributes of the received signal.

Based on the foregoing it should be apparent that the exemplary embodiments of this invention provide a method to reduce interference, the method comprising: determining at least one item of information unrelated to the target received signal; using the at least one item of information to obtain or determine an interference covariance matrix; and using the obtained interference covariance matrix with IRC to reduce interference.

The method of the previous paragraph, where a multiradio controller provides the time instance.

The method of the previous paragraph, where self-interference properties are predefined for the correct instance of time and bandwidth area of the receiver.

The method of the previous paragraph, where spatial properties are calculated beforehand by knowing the antenna geometry and/or correlation properties of the interference-causing transmit antenna.

The method of the previous paragraph, where spatial properties are calculated beforehand by knowing the antenna geometry and/or correlation properties of the receive antenna.

The method of the previous paragraph, where spatial properties are determined based on one or more measurements performed by the electronic device or any other suitable electronic device.

The method of the previous paragraph, where information and attributes required for the utilized model and accompanying covariance matrix are known, predefined or set by the electronic device.

The method of the previous paragraph, where information and attributes required for the utilized model and accompanying covariance matrix are obtained by measurements made at or substantially temporally close to the desired application of the covariance matrix.

The method of the previous paragraph, where information and attributes required for the utilized model and accompanying covariance matrix are obtained by measurements made prior to receiving the target received signal.

The method of the previous paragraph, where, if based on measurements, the measurements are performed by the electronic device and/or by other equipment.

The method of the previous paragraph, where, if based on measurements, the measurements are performed prior to, at or subsequent to sale or transfer (temporary or permanent) of the electronic device to a user.

The method of the previous paragraph, where the exemplary embodiment is implemented in a suitable component or components of the electronic device, such as one or more data processors, an antenna combiner, an IRC combiner, one or more multiradio controllers, an integrated circuit, an ASIC, circuitry, a computer program resident in memory coupled to a data processor, one or more communication interfaces, a transceiver, circuitry associated with a transceiver, and/or one or more of the above as located in a second electronic coupled to or in communication with a first electronic device.

The method of the previous paragraph, where, in order to adequately estimate interference covariance, averaging over time and/or frequency bandwidth is utilized.

The method of the previous paragraph, where averaging over subcarriers in an OFDMA system is performed.

The method of the previous paragraph, where a multiradio controller is used to obtain the signature (e.g., time, frequency, spatial properties) of a transmitted interfering signal.

Based on the foregoing it should be apparent that the exemplary embodiments of this invention provide a computer program product to reduce interference. The computer program product comprises program instructions embodied on a tangible computer-readable medium. Execution of the program instructions results in operations comprising: determining at least one item of information unrelated to a target received signal; using the at least one item of information to obtain or determine an interference covariance matrix; and using the obtained interference covariance matrix with IRC to reduce interference.

The computer program product of the above paragraph may further be modified in accordance with the discussion herein.

Based on the foregoing it should be apparent that the exemplary embodiments of this invention provide an apparatus, electronic device, communication device, circuitry and/or integrated circuit to reduce interference. Said apparatus may comprise: at least one data processor; at least one memory coupled to the at least one data processor; at least one transceiver coupled to the data processor; and at least one antenna coupled to the data processor and the at least one transceiver; wherein the data processor is configured to: determine at least one item of information unrelated to a target received signal; use the at least one item of information to obtain or determine an interference covariance matrix; and use the obtained interference covariance matrix with IRC to reduce interference.

The apparatus of the above paragraph may further be modified in accordance with the discussion herein.

Below are provided further descriptions of non-limiting, exemplary embodiments. The below-described exemplary embodiments are separately numbered for clarity and identification. This numbering should not be construed as wholly separating the below descriptions since various aspects of one or more exemplary embodiments may be practiced in conjunction with one or more other aspects or exemplary embodiments.

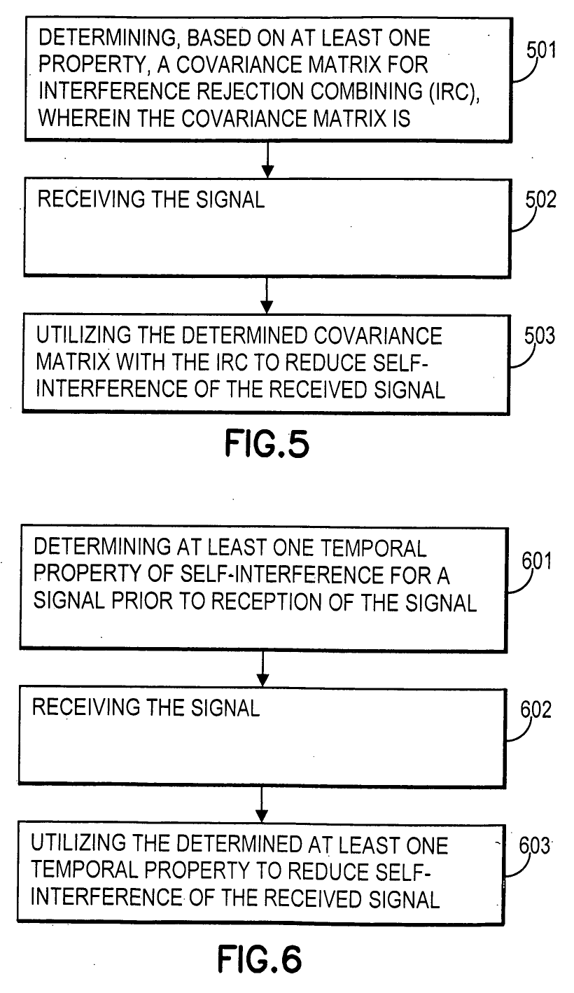

(1) In one non-limiting, exemplary embodiment, and as shown in FIG. 5, a method comprising: determining, based on at least one property, a covariance matrix for interference rejection combining (IRC), wherein the covariance matrix is determined prior to reception of a signal for which the IRC is to be used (box 501); receiving the signal (box 502); and utilizing the determined covariance matrix with the IRC to reduce self-interference of the received signal (box 503).

A method as above, wherein the at least one property comprises at least one of a temporal property and a spatial property. A method as in any above, wherein the at least one property comprises a spatial property based on at least one of antenna geometry and a correlation property of an interference-causing antenna. A method as in any above, wherein the at least one property comprises at least one of an instance of time for the self-interference and a bandwidth area of a receiver that is to receive the signal. A method as in any above, further comprising: performing at least one measurement; and determining the at least one property based on the at least one measurement. A method as in the previous, wherein the at least one measurement comprises a measurement of at least one of: bit error rate, block error rate, frame error rate, received energy per chip divided by the noise power density in the band (Ec/No), interference signal code power, received signal code power, received signal strength indicator, and signal-to-interference-power ratio (SIR). A method as in any above, wherein the method is implemented by a user equipment.

A method as in any above, further comprising: utilizing the determined covariance matrix to obtain antenna combining weights, wherein the IRC utilizes the obtained antenna combining weights. A method as in any above, wherein the covariance matrix is not based on the received signal. A method as in any above, wherein the received signal comprises a multiple-input multiple-output signal. A method as in any above, wherein the method is implemented by a multi-antenna apparatus, a user equipment, a multi-antenna user equipment, a mobile phone, or a multi-antenna mobile electronic device. A method as in any above, wherein the method is implemented by a computer program. A method as in any above, wherein the method is implemented by a computer program product comprising program instructions embodied on a tangible computer-readable medium, execution of the program instructions resulting in operations comprising the steps of the method.

(2) A computer program product comprising program instructions embodied on a tangible computer-readable medium, execution of the program instructions resulting in operations comprising: determining, based on at least one property, a covariance matrix for interference rejection combining (IRC), wherein the covariance matrix is determined prior to reception of a signal for which the IRC is to be used; receiving the signal; and utilizing the determined covariance matrix with the IRC to reduce self-interference of the received signal.

A computer program product as above, wherein the at least one property comprises at least one of a temporal property and a spatial property. A computer program product as in any above, wherein the at least one property comprises a spatial property based on at least one of antenna geometry and a correlation property of an interference-causing antenna. A computer program product as in any above, wherein the at least one property comprises at least one of an instance of time for the self-interference and a bandwidth area of a receiver that is to receive the signal. A computer program product as in any above, execution of the program instructions resulting in operations further comprising: performing at least one measurement; and determining the at least one property based on the at least one measurement. A computer program product as in the previous, wherein the at least one measurement comprises a measurement of at least one of: bit error rate, block error rate, frame error rate, received energy per chip divided by the noise power density in the band (Ec/No), interference signal code power, received signal code power, received signal strength indicator, and signal-to-interference-power ratio (SIR). A computer program product as in any above, wherein the program instructions are executed by a user equipment.

A computer program product as in any above, execution of the program instructions resulting in operations further comprising: utilizing the determined covariance matrix to obtain antenna combining weights, wherein the IRC utilizes the obtained antenna combining weights. A computer program product as in any above, wherein the covariance matrix is not based on the received signal. A computer program product as in any above, wherein the received signal comprises a multiple-input multiple-output signal. A computer program product as in any above, wherein the program instructions are executed by a multi-antenna apparatus, a user equipment, a multi-antenna user equipment, a mobile phone, or a multi-antenna mobile electronic device.

(3) An apparatus comprising: a processor configured to determine, based on at least one property, a covariance matrix for interference rejection combining (IRC), wherein the covariance matrix is determined by the processor prior to reception of a signal for which the IRC is to be used; and a receiver configured to receive the signal, wherein the processor is further configured to utilize the determined covariance matrix with the IRC to reduce self-interference of the received signal.

An apparatus as above, further comprising: a first antenna coupled to the receiver; and a second antenna, wherein the self-interference is due to a second signal received by or transmitted by the second antenna. An apparatus as in any above, further comprising: a measuring component configured to perform at least one measurement, wherein the processor is further configured to determine the at least one property based on the at least one measurement. An apparatus as in the previous, wherein the at least one measurement comprises a measurement of at least one of: bit error rate, block error rate, frame error rate, received energy per chip divided by the noise power density in the band (Ec/No), interference signal code power, received signal code power, received signal strength indicator, and signal-to-interference-power ratio (SIR). An apparatus as above, wherein the measuring component comprises the processor or the receiver. An apparatus as in any above, wherein the apparatus comprises a user equipment.

An apparatus as in any above, wherein the at least one property comprises at least one of a temporal property and a spatial property. An apparatus as in any above, wherein the at least one property comprises a spatial property based on at least one of antenna geometry and a correlation property of an interference-causing antenna. An apparatus as in any above, wherein the at least one property comprises at least one of an instance of time for the self-interference and a bandwidth area of a receiver that is to receive the signal. An apparatus as in any above, wherein the processor is further configured to utilize the determined covariance matrix to obtain antenna combining weights, wherein the IRC utilizes the obtained antenna combining weights. An apparatus as in any above, wherein the covariance matrix is not based on the received signal. An apparatus as in any above, wherein the received signal comprises a multiple-input multiple-output signal. An apparatus as in any above, wherein the apparatus comprises a multi-antenna apparatus, a user equipment, a multi-antenna user equipment, a mobile phone, or a multi-antenna mobile electronic device.

(4) An apparatus comprising: means for determining, based on at least one property, a covariance matrix for interference rejection combining (IRC), wherein the covariance matrix is determined by the processor prior to reception of a signal for which the IRC is to be used; means for receiving the signal; and means for utilizing the determined covariance matrix with the IRC to reduce self-interference of the received signal.

An apparatus as above, further comprising: first antenna means coupled to the means for receiving; and second antenna means, wherein the self-interference is due to a second signal received by or transmitted by the second antenna means. An apparatus as in any above, further comprising: means for performing at least one measurement, wherein the processor is further configured to determine the at least one property based on the at least one measurement. An apparatus as in the previous, wherein the at least one measurement comprises a measurement of at least one of: bit error rate, block error rate, frame error rate, received energy per chip divided by the noise power density in the band (Ec/No), interference signal code power, received signal code power, received signal strength indicator, and signal-to-interference-power ratio (SIR). An apparatus as above, wherein the means for performing at least one measurement comprises the means for determining, the means for receiving or the means for utilizing. An apparatus as in any above, wherein the apparatus comprises a user equipment. An apparatus as in any above, wherein the means for receiving comprises a receiver and the means for determining and means for utilizing comprise a processor.

An apparatus as in any above, wherein the at least one property comprises at least one of a temporal property and a spatial property. An apparatus as in any above, wherein the at least one property comprises a spatial property based on at least one of antenna geometry and a correlation property of an interference-causing antenna. An apparatus as in any above, wherein the at least one property comprises at least one of an instance of time for the self-interference and a bandwidth area of a receiver that is to receive the signal. An apparatus as in any above, further comprising: means for utilizing the determined covariance matrix to obtain antenna combining weights, wherein the IRC utilizes the obtained antenna combining weights. An apparatus as in any above, wherein the covariance matrix is not based on the received signal. An apparatus as in any above, wherein the received signal comprises a multiple-input multiple-output signal. An apparatus as in any above, wherein the apparatus comprises a multi-antenna apparatus, a user equipment, a multi-antenna user equipment, a mobile phone, or a multi-antenna mobile electronic device.

(5) In another non-limiting, exemplary embodiment, and as shown in FIG. 6, A method comprising: determining at least one temporal property of self-interference for a signal prior to reception of the signal (box 601); receiving the signal (box 602); and utilizing the determined at least one temporal property to reduce self-interference of the received signal (box 603).

A method as above, wherein the at least one temporal property comprises an instance of time or duration of the self-interference. A method as in any above, wherein a covariance matrix is not used for the instance of time or duration of the self-interference. A method as in any above, wherein the method is implemented by a user equipment. A method as in any above, wherein the received signal comprises a multiple-input multiple-output signal. A method as in any above, wherein the method is implemented by a multi-antenna apparatus, a user equipment, a multi-antenna user equipment, a mobile phone, or a multi-antenna mobile electronic device. A method as in any above, wherein the method is implemented by a computer program. A method as in any above, wherein the method is implemented by a computer program product comprising program instructions embodied on a tangible computer-readable medium, execution of the program instructions resulting in operations comprising the steps of the method.

(6) A computer program product comprising program instructions embodied on a tangible computer-readable medium, execution of the program instructions resulting in operations comprising: determining at least one temporal property of self-interference for a signal prior to reception of the signal; receiving the signal; and utilizing the determined at least one temporal property to reduce self-interference of the received signal.

A computer program product as above, wherein the at least one temporal property comprises an instance of time or duration of the self-interference. A computer program product as in any above, wherein a covariance matrix is not used for the instance of time or duration of the self-interference. A computer program product as in any above, wherein the program instructions are executed by a user equipment. A computer program product as in any above, wherein the received signal comprises a multiple-input multiple-output signal. A computer program product as in any above, wherein the program instructions are executed by a multi-antenna apparatus, a user equipment, a multi-antenna user equipment, a mobile phone, or a multi-antenna mobile electronic device.

(7) An apparatus comprising: a processor configured to determine at least one temporal property of self-interference for a signal prior to reception of the signal; and a receiver configured to receive the signal, wherein the processor is further configured to utilize the determined at least one temporal property to reduce self-interference of the received signal.

An apparatus as above, further comprising: a first antenna coupled to the receiver; and a second antenna, wherein the self-interference is due to a second signal received by or transmitted by the second antenna. An apparatus as in any above, wherein the at least one temporal property comprises an instance of time or duration of the self-interference. An apparatus as in any above, wherein a covariance matrix is not used for the instance of time or duration of the self-interference. An apparatus as in any above, wherein the apparatus comprises a user equipment. An apparatus as in any above, wherein the received signal comprises a multiple-input multiple-output signal. An apparatus as in any above, wherein the apparatus comprises a multi-antenna apparatus, a user equipment, a multi-antenna user equipment, a mobile phone, or a multi-antenna mobile electronic device.

(8) An apparatus comprising: means for determining at least one temporal property of self-interference for a signal prior to reception of the signal; means for receiving the signal; and means for utilizing the determined at least one temporal property to reduce self-interference of the received signal.

An apparatus as above, further comprising: first antenna means coupled to the means for receiving; and second antenna means, wherein the self-interference is due to a second signal received by or transmitted by the second antenna means. An apparatus as in any above, wherein the at least one temporal property comprises an instance of time or duration of the self-interference. An apparatus as in any above, wherein a covariance matrix is not used for the instance of time or duration of the self-interference. An apparatus as in any above, wherein the apparatus comprises a user equipment. An apparatus as in any above, wherein the received signal comprises a multiple-input multiple-output signal. An apparatus as in any above, wherein the apparatus comprises a multi-antenna apparatus, a user equipment, a multi-antenna user equipment, a mobile phone, or a multi-antenna mobile electronic device. An apparatus as in any above, wherein the means for receiving comprises a receiver and the means for determining and the means for utilizing comprise a processor.

The exemplary embodiments of the invention, as discussed above and as particularly described with respect to exemplary methods, may be implemented as a computer program product comprising program instructions embodied on a tangible computer-readable medium. Execution of the program instructions results in operations comprising steps of utilizing the exemplary embodiments or steps of the method.

It should be noted that the terms “connected,” “coupled,” or any variant thereof, mean any connection or coupling, either direct or indirect, between two or more elements, and may encompass the presence of one or more intermediate elements between two elements that are “connected” or “coupled” together. The coupling or connection between the elements can be physical, logical, or a combination thereof. As employed herein two elements may be considered to be “connected” or “coupled” together by the use of one or more wires, cables and/or printed electrical connections, as well as by the use of electromagnetic energy, such as electromagnetic energy having wavelengths in the radio frequency region, the microwave region and the optical (both visible and invisible) region, as several non-limiting and non-exhaustive examples.

While the exemplary embodiments have been described above in the context of various exemplary systems (e.g., GSM, Bluetooth®, WLAN in FIG. 1), it should be appreciated that the exemplary embodiments of this invention are not limited for use with only the disclosed types of wireless communication systems, and that they may be used to advantage in other wireless communication systems.

In general, the various exemplary embodiments may be implemented in hardware or special purpose circuits, software, logic or any combination thereof. For example, some aspects may be implemented in hardware, while other aspects may be implemented in firmware or software which may be executed by a controller, microprocessor or other computing device, although the invention is not limited thereto. While various aspects of the invention may be illustrated and described as block diagrams, flow charts, or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

The exemplary embodiments of the inventions may be practiced in various components such as integrated circuit modules. The design of integrated circuits is by and large a highly automated process. Complex and powerful software tools are available for converting a logic level design into a semiconductor circuit design ready to be etched and formed on a semiconductor substrate.

Programs, such as those provided by Synopsys, Inc. of Mountain View, Calif. and Cadence Design, of San Jose, Calif. automatically route conductors and locate components on a semiconductor chip using well established rules of design as well as libraries of pre-stored design modules. Once the design for a semiconductor circuit has been completed, the resultant design, in a standardized electronic format (e.g., Opus, GDSII, or the like) may be transmitted to a semiconductor fabrication facility or “fab” for fabrication.

The foregoing description has provided by way of exemplary and non-limiting examples a full and informative description of the invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of the non-limiting and exemplary embodiments of this invention.

Furthermore, some of the features of the preferred embodiments of this invention could be used to advantage without the corresponding use of other features. As such, the foregoing description should be considered as merely illustrative of the principles, teachings and exemplary embodiments of this invention, and not in limitation thereof.

What is claimed is:

1. A method comprising:
determining, based on at least one property, a covariance matrix for interference rejection combining (IRC), wherein the covariance matrix is determined prior to reception of a signal for which the IRC is to be used;
receiving the signal; and
utilizing the determined covariance matrix with the IRC to reduce self-interference of the received signal.

2. A method as in claim 1, wherein the at least one property comprises a spatial property based on at least one of antenna geometry and a correlation property of an interference-causing antenna.

3. A method as in claim 1, wherein the at least one property comprises at least one of an instance of time for the self-interference and a bandwidth area of a receiver that is to receive the signal.

4. A method as in claim 1, further comprising: performing at least one measurement; and determining the at least one property based on the at least one measurement.

5. A method as in claim 4, wherein the at least one measurement comprises a measurement of at least one of: bit error rate, block error rate, frame error rate, received energy per chip divided by the noise power density in the band (Ec/No), interference signal code power, received signal code power, received signal strength indicator, and signal-to-interference-power ratio (SIR).

6. A method as in claim 1, wherein the method is implemented by a user equipment.

7. A computer program product comprising program instructions embodied on a tangible computer-readable medium, execution of the program instructions resulting in operations comprising:
determining, based on at least one property, a covariance matrix for interference rejection combining (IRC), wherein the covariance matrix is determined prior to reception of a signal for which the IRC is to be used;
receiving the signal; and
utilizing the determined covariance matrix with the IRC to reduce self-interference of the received signal.

8. A computer program product as in claim 7, wherein the at least one property comprises a spatial property based on at least one of antenna geometry and a correlation property of an interference-causing antenna.

9. A computer program product as in claim 7, wherein the at least one property comprises at least one of an instance of time for the self-interference and a bandwidth area of a receiver that is to receive the signal.

10. A computer program product as in claim 7, wherein execution of the program instructions results in operations further comprising: performing at least one measurement; and determining the at least one property based on the at least one measurement.

11. A computer program product as in claim 10, wherein the at least one measurement comprises a measurement of at least one of: bit error rate, block error rate, frame error rate, received energy per chip divided by the noise power density in the band (Ec/No), interference signal code power, received signal code power, received signal strength indicator, and signal-to-interference-power ratio (SIR).

12. An apparatus comprising:
a processor configured to determine, based on at least one property, a covariance matrix for interference rejection combining (IRC), wherein the covariance matrix is determined by the processor prior to reception of a signal for which the IRC is to be used; and
a receiver configured to receive the signal,
wherein the processor is further configured to utilize the determined covariance matrix with the IRC to reduce self-interference of the received signal.

13. An apparatus as in claim 12, further comprising: a first antenna coupled to the receiver; and a second antenna, wherein the self-interference is due to a second signal received by or transmitted by the second antenna.

14. An apparatus as in claim 12, further comprising a measurement component configured to perform at least one measurement, wherein the processor is further configured to determine the at least one property based on the at least one measurement.

15. An apparatus as in claim 12, wherein the at least one property comprises at least one of: a spatial property based on antenna geometry, a spatial property based on a correlation property of an interference-causing antenna, an instance of time for the self-interference and a bandwidth area of the receiver.

16. An apparatus as in claim 12, wherein the apparatus comprises a user equipment.

17. A method comprising:
determining at least one temporal property of self-interference for a signal prior to reception of the signal;
receiving the signal; and
utilizing the determined at least one temporal property to reduce self-interference of the received signal.

18. A method as in claim 17, wherein the at least one temporal property comprises an instance of time or duration of the self-interference.

19. A method as in claim 18, wherein a covariance matrix is not used for the instance of time or duration of the self-interference.

20. A method as in claim 17, wherein the method is implemented by a user equipment.

21. An apparatus comprising:
a processor configured to determine at least one temporal property of self-interference for a signal prior to reception of the signal; and
a receiver configured to receive the signal;
wherein the processor is further configured to utilize the determined at least one temporal property to reduce self-interference of the received signal.

22. An apparatus as in claim 21, further comprising: a first antenna coupled to the receiver; and a second antenna, wherein the self-interference is due to a second signal received by or transmitted by the second antenna.

23. An apparatus as in claim 21, wherein the at least one temporal property comprises an instance of time or duration of the self-interference.

24. An apparatus as in claim 23, wherein a covariance matrix is not used for the instance of time or duration of the self-interference.

25. An apparatus as in claim 21, wherein the apparatus comprises a user equipment.
